(19) United States
(12) Patent Application Publication
(10) Pub. No.: US 2025/0334618 A1
(43) Pub. Date: Oct. 30, 2025

(54) METHOD AND SYSTEM FOR EVALUATING OPERATING STATE OF ELECTRIC ENERGY DATA ACQUISITION EQUIPMENT, AND MEDIUM

(71) Applicant: Sichuan Siji Technology Co., Ltd., Chengdu (CN)

(72) Inventors: Donglai TANG, Chengdu (CN); Ming HE, Chengdu (CN); Lijie DING, Chengdu (CN); Wenkang CHEN, Chengdu (CN); Mei YANG, Chengdu (CN); Sheng ZHONG, Chengdu (CN); Zeyu CHEN, Chengdu (CN); Fei XIE, Chengdu (CN); Yiyu GONG, Chengdu (CN); Qingyu LI, Chengdu (CN); Xiao NIE, Chengdu (CN); Guangzhi LIU, Chengdu (CN); Chuang DENG, Chengdu (CN); Le KANG, Chengdu (CN); Xu ZHONG, Chengdu (CN); Shijun FU, Chengdu (CN); Peng ZHOU, Chengdu (CN); Juli CHEN, Chengdu (CN); Shuyu HE, Chengdu (CN); Weisi LUO, Chengdu (CN); Qiming ZHANG, Chengdu (CN); Qiang MAO, Chengdu (CN); Yiqiu LI, Chengdu (CN); Linqian YU, Chengdu (CN); Shanshan YUAN, Chengdu (CN); Yi TANG, Chengdu (CN); Pan WANG, Chengdu (CN); Yi ZOU, Chengdu (CN)

(21) Appl. No.: 18/896,386

(22) Filed: Sep. 25, 2024

(30) Foreign Application Priority Data
Apr. 25, 2024 (CN) 202410501073.2

(51) Int. Cl. G01R 22/06

(52) U.S. Cl. CPC G01R 22/068

(57) ABSTRACT

The present disclosure discloses a method and a system for evaluating an operating state of electric energy data acquisition equipment, and a medium, and relates to the field of equipment state evaluation technologies. Firstly, regulation information of the electric energy data acquisition equipment is analyzed, and an operating state evaluation baseline of the electric energy data acquisition equipment is obtained. Operating profile data of the electric energy data acquisition equipment is acquired, and an operating state evaluation rule is established based on the operating profile data and the operating state evaluation baseline. Finally, operating state evaluation is performed on the electric energy data acquisition equipment based on the operating state evaluation rule, to obtain an operating state evaluation result.

### CROSS-REFERENCE TO RELATED APPLICATION

This application claims the benefit of Chinese Patent Application No.202410501073.2, filed on Apr. 25, 2024, which is hereby incorporated by reference in its entirety including any tables, figures, or drawings.

### TECHNICAL FIELD

The present disclosure relates to the field of equipment state evaluation technologies, and in particular, to a method and a system for evaluating an operating state of electric energy data acquisition equipment, and a medium.

### BACKGROUND

Electric energy data acquisition equipment (EDA) is an apparatus for acquiring electricity consumption data of a power distribution transformer, an end user, and the like, and has functions such as load management, electric energy usage monitoring, and line loss analysis. An operating state of the equipment directly affects stability of acquiring electric energy data of a customer. Under the background of promoting low carbon, the EDA, as important equipment for building a new-type power system, is a key step in promoting “electricity carbon reduction”. With continuous development of electronic technologies, an EDA upgrade speed is increased, and a conventional EDA periodical maintenance and replacement mode no longer meets a development requirement of data acquisition. Therefore, exploring of EDA operating state evaluation has a positive significance for improving electric energy data acquisition and management of the customer.

Many scholars have done a lot of research on EDA operating state evaluation, for example, perform EDA operating state evaluation through association rule mining and fault prediction; and process discrete distribution of EDA reliability by using a Bootstrap method, and fuse test data by using a Bayes method to perform EDA operating state evaluation; or perform EDA operating state evaluation by recognizing exception through density-based clustering or using an improved fading memory recursive least squares method; and determine an EDA failure mechanism by using a grey forecasting model, so as to perform EDA operating state evaluation. Therefore, there are various methods for performing EDA operating state evaluation. However, the foregoing method lacks tracing of a cause of EDA operating exceptionally, causing low accuracy of evaluating the EDA operating state.

### SUMMARY

A technical problem to be resolved in the present disclosure is that a conventional method for evaluating an operating state of electric energy data acquisition equipment lacks tracing and analysis of a cause of operating exceptionally of the electric energy data acquisition equipment, causing low accuracy of evaluating the EDA operating state. An objective of the present disclosure is to provide a method and a system for evaluating an operating state of electric energy data acquisition equipment, and a medium, so that when operating state evaluation is performed on the electric energy data acquisition equipment based on an operating state evaluation rule, a weight of an operating state evaluation indicator is adjusted by using a fault factor of the operating state evaluation rule, to improve accuracy of evaluating the operating state of the electric energy data acquisition equipment.

The present disclosure is implemented by the following technical solutions:

The present disclosure provides a method for evaluating an operating state of electric energy data acquisition equipment, including:
analyzing regulation information of the electric energy data acquisition equipment, and obtaining an operating state evaluation baseline of the electric energy data acquisition equipment;
acquiring operating profile data of the electric energy data acquisition equipment, and establishing an operating state evaluation rule based on the operating profile data and the operating state evaluation baseline; and
performing operating state evaluation on the electric energy data acquisition equipment based on the operating state evaluation rule, to obtain an operating state evaluation result, and in an operating state evaluation process of the electric energy data acquisition equipment, adjusting a weight of the operating state evaluation indicator based on a fault factor of the operating state evaluation rule.

In a further optimization solution, the analyzing regulation information of the electric energy data acquisition equipment, and obtaining an operating state evaluation baseline of the electric energy data acquisition equipment specifically includes:
obtaining the regulation information of the electric energy data acquisition equipment;
recognizing operating state red line information from the regulation information, where the operating state red line information includes text recognition information and content recognition information; and
using the operating state red line information as the operating state evaluation baseline of the electric energy data acquisition equipment.

In a further optimization solution, before the establishing an operating state evaluation rule based on the operating profile data and the operating state evaluation baseline, the method further includes:
cleaning exception data of the operating profile data, and fitting data points in an exception data range to eliminate the exception data.

In a further optimization solution, the establishing an operating state evaluation rule based on the operating profile data and the operating state evaluation baseline specifically includes:
clustering the operating profile data to distinguish between invalid exception data and equipment fault data, where the equipment fault data includes an equipment fault type, a fault cause, and a feature data item that correspond to each other;
forming an evaluation relationship between the equipment fault data and the fault cause based on the operating state evaluation baseline and exception detection in an equipment fault handling process;
tracing an equipment fault cause based on a tracing algorithm, and forming an algorithm tracing relationship between the equipment fault data and the fault cause; and
associating the evaluation relationship with the algorithm tracing relationship, and using consistency between the evaluation relationship and the algorithm tracing relationship as an operating state evaluation indicator.

In a further optimization solution, the forming an evaluation relationship between the equipment fault data and the fault cause based on the operating state evaluation baseline and exception detection in an equipment fault handling process specifically includes:
obtaining a current feature data item of the electric energy data acquisition equipment, comparing the current feature data item with a corresponding operating state evaluation baseline, and if the current feature data item exceeds the corresponding operating state evaluation baseline, obtaining a corresponding fault cause through matching.

In a further optimization solution, the performing operating state evaluation on the electric energy data acquisition equipment based on the operating state evaluation rule, to obtain an operating state evaluation result specifically includes:
obtaining a fault factor that affects the weight of the operating state evaluation indicator, and calculating a fault factor information entropy of the operating state evaluation indicator;
combining fault factor information entropies of a plurality of operating state evaluation indicators to obtain an operating state evaluation joint entropy;
adjusting the weight of the operating state evaluation indicator based on the operating state evaluation joint entropy; and
performing operating state evaluation on the electric energy data acquisition equipment based on an adjustment result of the weight of the operating state evaluation indicator.

In a further optimization solution, the combining fault factor information entropies of a plurality of operating state evaluation indicators to obtain an operating state evaluation joint entropy specifically includes:
obtaining fault factor information entropies of a plurality of operating state evaluation indicators, and using an intersection set of the fault factor information entropies of the plurality of operating state evaluation indicators as a conditional entropy of the operating state evaluation indicator; and
adding the fault factor information entropies of the operating state evaluation indicators, and performing summation on the fault factor information entropies and the conditional entropy of the operating state evaluation indicator to obtain the operating state evaluation joint entropy.

In a further optimization solution, the performing operating state evaluation on the electric energy data acquisition equipment based on the operating state evaluation rule, to obtain an operating state evaluation result further includes: raising an exception operating state alarm on electric energy data acquisition equipment whose operating state evaluation joint entropy is less than a first exception threshold.

To resolve the foregoing technical problem, the present disclosure further provides a system for evaluating an operating state of electric energy data acquisition equipment, configured to implement the foregoing method for evaluating an operating state of electric energy data acquisition equipment, where the system includes:
an analysis module, configured to: analyze regulation information of the electric energy data acquisition equipment, and obtain an operating state evaluation baseline of the electric energy data acquisition equipment;
an establishment module, configured to: acquire operating profile data of the electric energy data acquisition equipment, and establish an operating state evaluation rule based on the operating profile data and the operating state evaluation baseline; and
an evaluation module, configured to: perform operating state evaluation on the electric energy data acquisition equipment based on the operating state evaluation rule, to obtain an operating state evaluation result, and in an operating state evaluation process of the electric energy data acquisition equipment, adjust a weight of the operating state evaluation indicator based on a fault factor of the operating state evaluation rule.

To resolve the foregoing technical problem, the present disclosure further provides a computer readable medium storing a computer program thereon, where the computer program is executed by a processor to implement the foregoing method for evaluating an operating state of electric energy data acquisition equipment.

Compared with the conventional technology, the present disclosure has the following advantages and beneficial effects:

The present disclosure provides a method and a system for evaluating an operating state of electric energy data acquisition equipment, and a medium. Red line information is extracted from regulation information of the electric energy data acquisition equipment, to provide a baseline for an operating state evaluation process of the electric energy data acquisition equipment to obtain an operating state evaluation rule. When operating state evaluation is performed on the electric energy data acquisition equipment based on the operating state evaluation rule, a weight of an operating state evaluation indicator is adjusted based on a fault factor of the operating state evaluation rule, to form the combined weight of the operating state evaluation indicator and a fault factor of the electric energy data acquisition equipment, thereby improving accuracy of evaluating the operating state of the electric energy data acquisition equipment.

According to the method and the system for evaluating an operating state of electric energy data acquisition equipment, and the medium provided in the present disclosure, before the operating state evaluation rule is established based on the operating profile data and the operating state evaluation baseline, exception data of the operating profile data is cleaned, data points in an exception data range are fitted to eliminate the exception data, and preprocessing is performed on the operating profile data, so as to reduce impact of errors and missing data on the evaluation process.

### BRIEF DESCRIPTION OF DRAWINGS

To more clearly describe the technical solutions of the example implementations of the present disclosure, the accompanying drawings required in the embodiments are described briefly below. It should be understood that the following accompanying drawings illustrate only some embodiments of the present disclosure and therefore should not be construed as a limitation on the scope thereof. For a person of ordinary skill in the art, other relevant accompanying drawings can also be obtained from these accompanying drawings without any creative effort. In the accompanying drawings:

FIG. 1 is a schematic flowchart of a method for evaluating an operating state of electric energy data acquisition equipment;

FIG. 2 is a schematic flowchart of a method for obtaining an operating state evaluation baseline;

FIG. 3 is a schematic flowchart of establishing an operating state evaluation rule;

FIG. 4 is a schematic diagram of a decomposition principle of an FTA;

FIG. 5 is a schematic flowchart of obtaining an operating state evaluation result;

FIG. 6 is a schematic diagram of a principle of calculating an EDA operating state joint entropy; and

FIG. 7 is a schematic diagram of a system for evaluating an operating state of electric energy data acquisition equipment.

### DESCRIPTION OF EMBODIMENTS

The following describes example embodiments of the present disclosure in more detail with reference to the accompanying drawings. Although example embodiments of the present disclosure are shown in the accompanying drawings, it should be understood that the present disclosure may be implemented in various forms without being limited by the embodiments described herein. In contrast, these embodiments are provided to enable a more thorough understanding of the present disclosure and to enable the scope of the present disclosure to be fully conveyed to a person skilled in the art.

A conventional method for evaluating an operating state of electric energy data acquisition equipment lacks tracing and analysis of a cause of operating exceptionally of the electric energy data acquisition equipment, resulting in low accuracy of evaluating the EDA operating state. The present disclosure provides the following embodiments to resolve the foregoing technical problem.

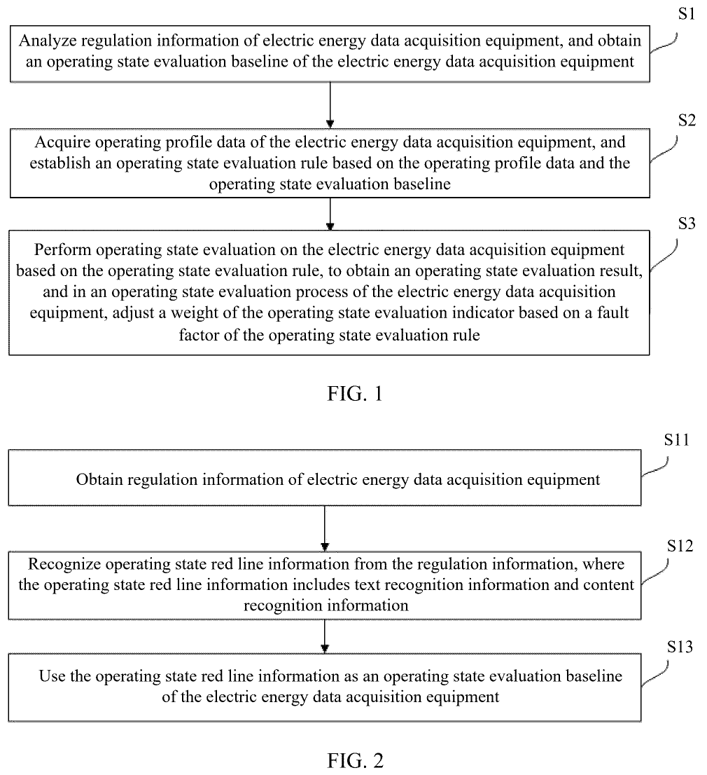

Embodiment 1: This embodiment provides a method for evaluating an operating state of electric energy data acquisition equipment. As shown in FIG. 1, the method includes the following steps:

S1. Analyze regulation information of the electric energy data acquisition equipment, and obtain an operating state evaluation baseline of the electric energy data acquisition equipment.

Step S1 specifically includes sub-steps shown in FIG. 2:

S11. Obtain the regulation information of the electric energy data acquisition equipment.

The regulation information includes national and industry regulations on the electric energy data acquisition equipment. EDA is used below to represent some electric energy data acquisition equipment. The regulation information is usually issued in the form of text electronic documents instead of structured data. Therefore, it is necessary to obtain a regulation information text document related to the electric energy data acquisition equipment.

S12. Recognize operating state red line information from the regulation information, where the operating state red line information includes text recognition information and content recognition information, and the red line information is equivalent to threshold information, which means that an alarm need to be generated if the threshold information is exceeded.

In this step, the recognized operating state red line information mainly includes two parts: the text recognition information and the content recognition information. For the text recognition information, image information of a regulation text is converted into a text character based on optical character recognition (OCR). Content recognition is used to extract a meaning of a regulation from the text character converted through OCR or directly from the regulation text.

For the text recognition information, a connectionist temporal classification (CTC) model is one of optical character recognition algorithms. Based on a conditional random field model, the optical character recognition algorithm resolves, by using a neural network, a problem that an input sequence and an output sequence in a text have different lengths and cannot be aligned. The CTC model can effectively recognize image texts of various EDA operating state evaluation regulations. Therefore, in this solution, the CTC model is used to perform text recognition on the regulation information.

A specific recognition process of the CTC model includes the following steps:
obtaining a regulation text document image, and assuming that character areas are relatively independent after the regulation text document image is segmented, where a posterior probability of a regulation text character is a cumulative probability of all the character areas in the image. A posterior probability c^{POS} of regulation text recognition is given in Formula (1):

$${c}^{POS} = {\prod }_{i = 1}^{{n}^{POS}} {o}_{i}^{POS} . \qquad ( 1 )$$

In this formula, n^{POS} is a quantity of lengths of regulation text characters that are input into the CTC model, and

$${o}_{i}^{POS}$$

is a probability of recognizing elements of regulation text characters for different character length quantities.

A true value probability c^{TRU} of the regulation text character in the CTC model is given in Formula (2):

$${c}^{TRU} = {\sum }_{i = 1}^{{n}^{TRU}} {o}_{i}^{TRU} . \qquad ( 2 )$$

In this formula, n^{TRU} is a quantity of recognized regulation text characters in the CTC model, and

$${o}_{i}^{TRU}$$

is a probability value of recognizing different regulation text characters.

A regulation text recognition result c^{RES} based on the CTR model is given in Formula (3):

$${c}^{RES} = arg max \prod {c}^{TRU} . \qquad ( 3 )$$

For the content recognition information, in this solution, content recognition is performed on the regulation information based on a hidden Markov model (HMM model). A process of applying the HMM model to text content recognition includes two parts: learning and decoding. The learning part is a process of importing and training a text rule by using the HMM model. A labeled text rule sample set is trained by using a maximum likelihood (ML) algorithm, and an HMM text recognition model is established. In the decoding part, a to-be-recognized text is solved to obtain a maximum probability text recognition result that includes a hidden state. The HMM model may be used to extract text information, relationship information, and the like from a sequence, and is characterized by accuracy in text extraction.

In the process of importing and training the text rule by using the HMM model, various EDA regulation text block methods are used. An EDA regulation text block is used as a basic unit for HMM model learning to mine and integrate contextual features so as to improve a training effect of the HMM model.

During training of the ML algorithm, a state probability, a transition state probability, and an observation state probability of the HMM model are obtained from a labeled EDA regulation text. An initial state probability c^{ML} of the EDA regulation is given in Formula (4):

$${c}^{ML} = \frac{{L}_{i}}{{{\sum }_{j = 1}}^{{n}^{ML}} {Z}_{j}} . \qquad ( 4 )$$

In this formula, Lᵢ is a quantity of EDA regulation text blocks that start with a state i in all EDA regulation text blocks, n^{ML} is a quantity of all EDA regulation training text blocks. Zⱼ is all different labeled EDA regulation text blocks.

The transition state probability c^{TRF} of the EDA regulation is given in Formula (5):

$${c}^{TRF} = \frac{{F}_{ij}}{{\sum }_{k = 1}^{{n}^{TRF}} {F}_{k}} . \qquad ( 5 )$$

In this formula, Fᵢⱼ is a quantity of times that an EDA regulation state is transitioned from the state i to a state j, n^{TRF} is a quantity of times that the EDA regulation state is transitioned from the state i to all states, and Fₖ is transition values of different EDA regulation states.

The observation state probability c^{OBS} of the EDA regulation is given in Formula (6):

$${c}^{OBS} = {B}_{j} / {\sum }_{i = 1}^{{n}^{OBS}} {B}_{i} . \qquad ( 6 )$$

In this formula, Bⱼ is a release observation value count that the EDA regulation state is transitioned from the state i to the state j, n^{OBS} is a release observation value count that the EDA regulation state is transitioned from the state i to all states, and Bᵢ is release observation values of transition of different EDA regulation states.

After the EDA regulation text is trained, an optimal HMM text recognition model is obtained.

The decoding part includes three parts: preprocessing an EDA regulation text header, solving an optimal state, and outputting an EDA regulation text recognition result. During the preprocessing of the EDA regulation information text header, blocking preprocessing is performed on the to-be-recognized EDA regulation information text. During the solving of the optimal state, the to-be-recognized EDA regulation text is solved by using the trained HMM text recognition model.

A random variable at a current moment in the HMM text recognition model is determined by a value at a previous moment. When an EDA red line information sequence Y=(y₁, y₂, . . . , yₘ) is determined, yₘ represents operating state red line information of an m^{th} EDA information sequence. A labeled sequence is X=(x₁, x₂, . . . , x_{ψ}), where x₁₀₄ represents operating state red line information of a labeled sequence of a ψ^{th} labeled EDA. A red line probability Q(x₁, y₁, x₂, y₂, . . . , xₙ, yₘ) is calculated according to Formula (7):

$$Q ( {x}_{1} , {y}_{1} , {x}_{2} , {y}_{2} , … {x}_{ψ} , {y}_{m} ) = Q ( {y}_{1} ) Q ( {x}_{1} \vert {y}_{1} ) {\prod }_{k = 2}^{m} Q ( {y}_{k} \vert {y}_{k - 1} ) Q ( {x}_{k} \vert {y}_{k} ) \qquad ( 7 )$$

In this formula, Q(y₁) is an initial state probability of extraction of the EDA regulation red line, Q(yₖ|yₖ₋₁) is a state transition probability of extraction of different EDA regulation red lines, m is a quantity of possible EDA regulation red lines, Q(xₖ|yₖ) is an observation output probability of different EDA regulation red lines, and Q(x₁|y₁) is an observation output probability of the first EDA regulation red line.

After the initial state probability, the state transition probability, and the observation output probability of extraction of the foregoing EDA regulation red line are obtained, a maximum labeled sequence of a corresponding probability of the EDA regulation red line is calculated according to a Viterbi algorithm, that is, extraction of the red line information in the EDA regulation is completed.

S13. Use the operating state red line information as the operating state evaluation baseline of the electric energy data acquisition equipment.

In this step, the foregoing EDA regulation red line information is used as the EDA operating state evaluation baseline.

The EDA regulation red line information extracted in this solution mainly includes two types: a meter and a terminal. Red lines of the meter are as follows: the 97 protocol, a 09 version of meter, a 12 version of meter, an imported meter, a clock fault, built-in switch exception, an operating life greater than 8 years, a software defect, and a 13 version of meter connected to a 698 terminal. Red lines of the terminal are as follows: a 09 version of terminal, unmanned operation and maintenance, old hardware, clock exception, embedded secure access module (ESAM) exception, a 13 version of acquisition terminal that contains a 20 version of power meter.

S2. Acquire operating profile data of the electric energy data acquisition equipment, and establish an operating state evaluation rule based on the operating profile data and the operating state evaluation baseline.

A purpose of establishing the EDA operating state evaluation rule is to provide a basis for a detailed evaluation rule thereof. There are a plurality of EDA types. The EDA operating state evaluation rule is established to simulate a manual EDA fault analysis process. An EDA fault search method is determined by using an exception parameter. The EDA operating state is analyzed by using an EDA fault rule.

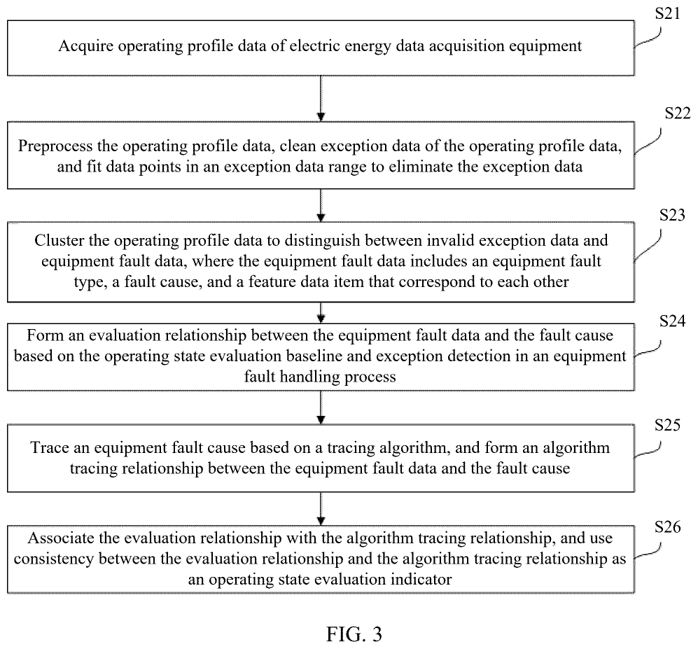

As shown in FIG. 3, in this solution, step S2 specifically includes the following sub-steps:

S21. Acquire operating profile data of the electric energy data acquisition equipment.

S22. Preprocess the operating profile data, clean exception data of the operating profile data, and fit data points in an exception data range to eliminate the exception data.

In this step, the operating profile data is mainly EDA acquisition data. The EDA acquisition data includes information such as daily frozen reading information, voltage, current, phase information, and exception event data. The EDA acquisition data is affected by factors such as an EDA equipment fault, exception electric energy usage behavior, and absence of a main data attribute. The EDA acquisition data has exception. Exception EDA data usually includes null data, format error data, and logical conflict data, which may cause deviation of an analysis result of EDA operating state evaluation. To ensure accuracy of evaluating the EDA operating state, the EDA operating profile data is preprocessed to reduce an impact of errors and missing data on the evaluation model.

Preferably, in this solution, the EDA operating profile data is preprocessed based on a Savitzky-Golay filter (SG filter).

The exception data is cleaned through convolution based on the SG filter, and a least squares method is used to fit the data points in the exception data range, to eliminate the exception data. A specific method is as follows:

The EDA operating profile data e^{SG} fitted based on the SG filter is given in Formula (8):

$${e}^{SG} = {\sum }_{j = 1}^{{n}^{SG}} {e}_{j}^{DAQ} {t}^{k} . \qquad ( 8 )$$

In this formula,

$${e}_{j}^{DAQ}$$

is EDA acquisition window data of different orders, n^{SG} is an order of the SG filter, and t^{k} is k^{th} power of an EDA collection time.

Preferably, in this embodiment, after the EDA operating profile data is fitted based on the SG filter, an optimal repair effect of the EDA operating profile data is solved by using the least squares method. After an order and a quantity of boundaries of the EDA operating profile data are determined, convolution processing is performed on the EDA operating profile data to obtain the cleaned data e^{OUT} given in Formula (9):

$${e}^{OUT} = \frac{1}{{n}^{OLS}} {\sum }_{i = 1}^{{n}^{OLS}} {e}_{i}^{POD} {o}_{i} . \qquad ( 9 )$$

In this formula, n^{OLS} is a quantity of polynomial fitting times when the least squares method is used to calculate the EDA acquisition data,

$${e}_{i}^{POD}$$

is EDA acquisition raw data output by SG filters with different values, and oᵢ is smoothing coefficients with different values for fitting the EDA acquisition data.

S23. Cluster the operating profile data to distinguish between invalid exception data and equipment fault data, where the equipment fault data includes an equipment fault type, a fault cause, and a feature data item that correspond to each other.

Profile information, daily frozen reading information, voltage, current, phase information, and an exception event in the EDA operating profile data are clustered to obtain EDA feature data item, and then the EDA operating state evaluation rule is established on this basis.

Preferably, in this solution, density-based spatial clustering of applications with noise (DBSCAN) is used to distinguish between the meaningless exception data and the EDA equipment fault data.

The DBSCAN algorithm is a clustering method for performing noise processing and density analysis. Based on a conventional density-based clustering algorithm, a noise resistance processing step to measure clustering distribution by using a neighborhood parameter is added. When there are few input parameters, the DBSCAN algorithm can still divide high-density areas into clusters, and can find clusters of various shapes in spatial noise data. The algorithm is characterized by high clustering efficiency, no need to specify a quantity of clusters, and a strong noise resistance capability.

Preferably, in this solution, a distance between samples of the EDA operating profile data is calculated by using a Mahalanobis distance. The Mahalanobis distance comprehensively considers a feature relationship between the samples of the EDA operating profile data, and uses covariance calculation, which is characterized by accurate calculation. A specific process includes:

The Mahalanobis distance

$${d}_{ij}^{DBS}$$

between an i^{th} sample and a j^{th} sample of the EDA operating profile data is given in Formula (10):

$${d}_{ij}^{DBS} = \sqrt{{( {h}_{i} - {h}_{j} )}^{{m}^{DBS}} {γ}^{- 1} ( {h}_{i} - {h}_{j} )} . \qquad ( 10 )$$

In this formula, hᵢ and hⱼ are respectively an i^{th} sample value and a j^{th} sample value of the EDA operating profile data, and m^{DBS} is a sample feature quantity of the EDA operating profile data, and γ is a Mahalanobis distance covariance matrix.

Preferably, the DBSCAN algorithm in this solution uses a neighborhood parameter to describe whether clustering distribution of the EDA operating profile data is compact, and has a noise resistance characteristic. The EDA operating profile data field meets a constraint

$${s}_{ij}^{DBS}$$

given in Formula (11):

$${s}_{ij}^{DBS} = \{ {h}_{i} ∈ {F}^{DBS} \vert {d}_{ij}^{DBS} \leq λ \} . \qquad ( 11 )$$

In this formula, F^{DBS} is a density circle radius in the DBSCAN algorithm, and λ is a neighborhood parameter in the DBSCAN algorithm.

S24. Form an evaluation relationship between the equipment fault data and the fault cause based on the operating state evaluation baseline and exception detection in an equipment fault handling process.

Preferably, the step specifically includes the following process: obtaining a current feature data item of the electric energy data acquisition equipment, comparing the current feature data item with a corresponding operating state evaluation baseline, and if the current feature data item exceeds the corresponding operating state evaluation baseline, obtaining a corresponding fault cause through matching.

The equipment fault data includes an equipment fault type, a fault cause, and a feature data item that correspond to each other. For an equipment fault type, feature data generated by different fault causes is different. In this solution, a matching correspondence between the equipment fault type, the fault cause, and the feature data item is mined, to reflect the evaluation relationship between the equipment fault data and the fault cause, so that the fault cause participates in the operating state evaluation process of the electric energy data acquisition equipment, thereby improving evaluation accuracy.

In an actual application environment, the EDA equipment fault type includes a software configuration fault and a hardware fault. The hardware fault includes an online fault and an offline fault.

The software configuration fault is caused by a communication protocol, a software defect, and the like of the EDA equipment. The software configuration fault results in exception of an EDA rate count, a missing rate item, and unequal reading data exception. In view of this, in this solution, a current feature data item (a rate count, whether rate item is missing, or whether reading is equal) is compared with a corresponding operating state evaluation baseline, and a feature data item that exceeds the operating state evaluation baseline data is a corresponding fault cause.

The online fault is a clock fault, a built-in switch exception, and the like. Such fault causes data such as EDA time scale exception and terminal meter reading time exception. In view of this, in this solution, a current feature data item (a time scale and a terminal meter reading time) is compared with a corresponding operating state evaluation baseline, and a feature data item that exceeds the baseline data is a corresponding fault cause.

Specially, the offline fault is caused by communication disconnection between the EDA equipment and an acquisition master station. Such fault includes damage of an EDA communication module and burning of the EDA. During EDA operating state evaluation, the fault cause is not traced, and the EDA fault is directly determined.

S25. Trace an equipment fault cause based on a tracing algorithm, and form an algorithm tracing relationship between the equipment fault data and the fault cause.

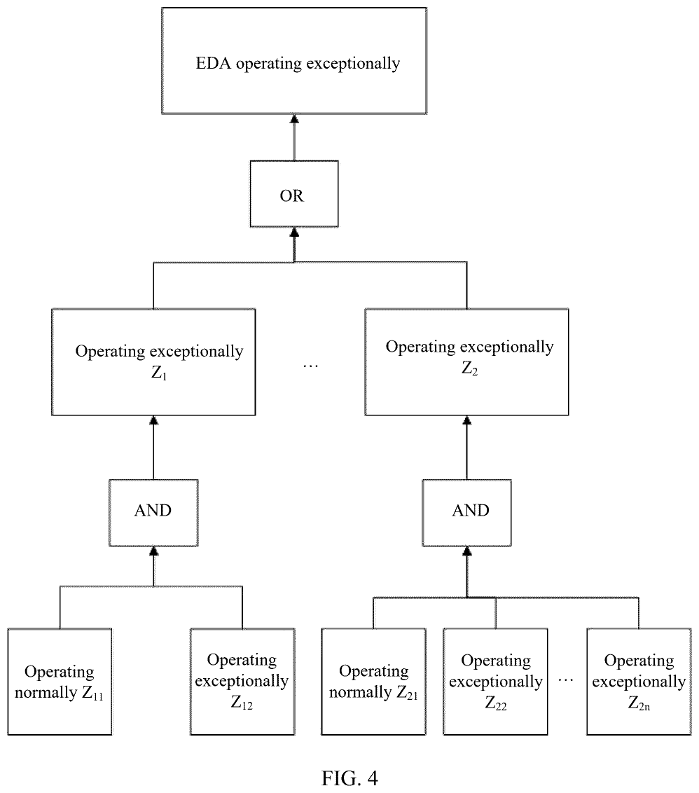

Preferably, in algorithm tracing, in this solution, based on a fault tree analysis (FTA) algorithm, a fault that has greatest impact on the EDA is first determined as the top of the tree, and then causes affecting the EDA fault are decomposed step by step until a bottom-level basic event is formed. As shown in FIG. 4, a fault tree in this embodiment is divided into three levels of events: Basic events such as operating normally Z₁₁ and operating exceptionally Z₁₂ constitute an intermediate event such as operating exceptionally Z₁ by using an “and” relationship, basic events such as operating normally Z₂₁, operating exceptionally Z₂₂, . . . , and operating exceptionally Z₂ₙ constitute an intermediate event such as operating exceptionally Z₂ by using an “and” relationship. The intermediate events constitute a high-level event by using an “or” relationship.

S26. Associate the evaluation relationship with the algorithm tracing relationship, and use consistency between the evaluation relationship and the algorithm tracing relationship as an operating state evaluation indicator.

S3. Perform operating state evaluation on the electric energy data acquisition equipment based on the operating state evaluation rule, to obtain an operating state evaluation result, and in an operating state evaluation process of the electric energy data acquisition equipment, adjust a weight of the operating state evaluation indicator based on a fault factor of the operating state evaluation rule.

Environment factors have strong impact on EDA operating features, resulting in different EDA operating features in different regions. Therefore, EDA operating state evaluation rules of a same scale have poor adaptability in different regions. A fault factor (FF) is a factor that affects the weight of EDA operating state evaluation indicator. An information entropy is usually used to define a degree of impact of FF. When the information entropy of FF is smaller, a degree of dispersion affecting the EDA operating state indicator is larger, the weight that affects the EDA operating state indicator is larger. Otherwise, the weight is smaller. FF is characterized by adapting to differences between EDA operating features in different regions. Therefore, preferably, in this solution, the weight of the EDA operating state evaluation indicator is adjusted based on the fault factor, thereby improving adaptability of the EDA operating state evaluation in different regions.

As shown in FIG. 5, step S3 specifically includes the following sub-steps:

S31. Obtain a fault factor that affects the weight of the operating state evaluation indicator, and calculate a fault factor information entropy of the operating state evaluation indicator. An FF entropy value w^{FF} of the operating state evaluation indicator is given in Formula (12):

$${w}^{FF} = - {e}^{SPL} {\sum }_{j = 1}^{{n}^{FF}} {r}_{j}^{FF} ln ( {r}_{j}^{FF} ) {u}_{j} . \qquad ( 12 )$$

In this formula, e^{SPL} is a sample value of EDA operating state evaluation, n^{FF} is a quantity of information entropies of the EDA operating state evaluation indicator,

$${r}_{j}^{FF}$$

is a ratio of different EDA operating state evaluation indicators to overall indicators, and uⱼ is weights of different EDA operating state evaluation indicators.

S32. Combine fault factor information entropies of a plurality of operating state evaluation indicators to obtain an operating state evaluation joint entropy.

The EDA operating state evaluation FF is an information entropy of a single EDA evaluation indicator. In an actual evaluation process, a plurality of EDA operating state evaluation FFs need to be combined to form an overall EDA operating state evaluation entropy value, namely, the EDA operating state evaluation joint entropy.

Step S32 specifically includes the following process:
obtaining fault factor information entropies of a plurality of operating state evaluation indicators, and using an intersection set of the fault factor information entropies of the plurality of operating state evaluation indicators as a conditional entropy of the operating state evaluation indicator; and
adding the fault factor information entropies of the operating state evaluation indicators, and performing summation on the fault factor information entropies and the conditional entropy of the operating state evaluation indicator to obtain the operating state evaluation joint entropy. The EDA operating state evaluation joint entropy w^{UNION} is given in Formula (13):

$${w}^{UNION} = w ( {g}_{1} ) + w ( {g}_{2} ) + … + w ( {g}_{m} ) + w ( {g}_{1} \vert {g}_{2} \vert … \vert {g}_{m} ) . \qquad ( 13 )$$

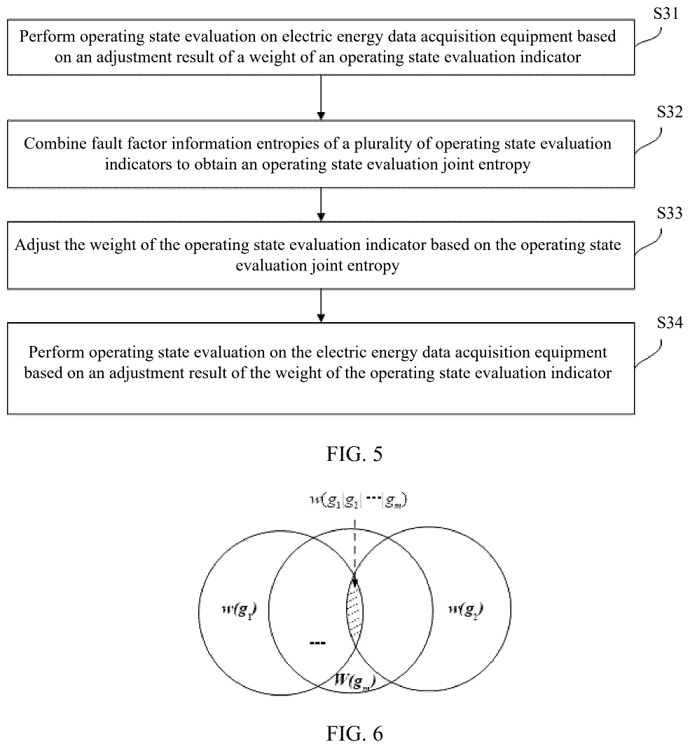

In this formula, m is a quantity of EDA operating state evaluation indicators, w(g₁), w(g₂), w(gₘ) are respectively information entropies of the first, second, and m^{th} EDA operating state evaluation indicators, and w(g₁|g₂|. . . |gₘ) is the conditional entropy of the EDA operating state evaluation indicator. As shown in FIG. 6, the conditional entropy of the EDA operating state evaluation indicator is an intersection set of the fault factor information entropies of the plurality of EDA operating state evaluation indicators.

S33. Adjust the weight of the operating state evaluation indicator based on the operating state evaluation joint entropy.

S34. Perform operating state evaluation on the electric energy data acquisition equipment based on an adjustment result of the weight of the operating state evaluation indicator.

The method further includes: raising an exception operating state alarm on electric energy data acquisition equipment whose operating state evaluation joint entropy is less than a first exception threshold.

Preferably, the first exception threshold in this solution is an exception threshold standardΔƒ in the power industry association.

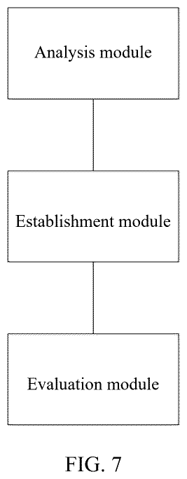

Embodiment 2: This embodiment provides a system for evaluating an operating state of electric energy data acquisition equipment, configured to implement the method for evaluating an operating state of the electric energy data acquisition equipment in Embodiment 1. As shown in FIG. 7, the system includes:
an analysis module, configured to: analyze regulation information of the electric energy data acquisition equipment, and obtain an operating state evaluation baseline of the electric energy data acquisition equipment;
an establishment module, configured to: acquire operating profile data of the electric energy data acquisition equipment, and establish an operating state evaluation rule based on the operating profile data and the operating state evaluation baseline; and
an evaluation module, configured to: perform operating state evaluation on the electric energy data acquisition equipment based on the operating state evaluation rule, to obtain an operating state evaluation result, and in an operating state evaluation process of the electric energy data acquisition equipment, adjust a weight of the operating state evaluation indicator based on a fault factor of the operating state evaluation rule.

In a specific implementation process of this embodiment, the analysis module specifically includes: a first acquisition unit, where the first collection unit is configured to obtain the regulation information of the electric energy data acquisition equipment; a recognition unit, configured to recognize operating state red line information from the regulation information, where the operating state red line information includes text recognition information and content recognition information; and an output unit, configured to use the operating state red line information as the operating state evaluation baseline of the electric energy data acquisition equipment for output.

In a specific implementation process of this embodiment, the establishment module specifically includes: a second acquisition unit, where the second acquisition unit is configured to acquire operating profile data of the electric energy data acquisition equipment; a preprocessing unit, where the preprocessing unit is configured to: clean exception data of the operating profile data, and fit data points in an exception data range to eliminate the exception data; a clustering unit, where the clustering unit is configured to cluster the operating profile data to distinguish between invalid exception data and equipment fault data, where the equipment fault data includes an equipment fault type, a fault cause, and a feature data item that correspond to each other; a first construction unit, where the first construction unit is configured to form an evaluation relationship between the equipment fault data and the fault cause based on the operating state evaluation baseline and exception detection in an equipment fault handling process; a second construction unit, where the second construction unit is configured to: trace an equipment fault cause based on a tracing algorithm, and form an algorithm tracing relationship between the equipment fault data and the fault cause, where specifically a current feature data item of the electric energy data acquisition equipment is obtained, the current feature data item is compared with a corresponding operating state evaluation baseline, and if the current feature data item exceeds the corresponding operating state evaluation baseline, a corresponding fault cause is obtained through matching; and a second output unit, where the second output unit is configured to: associate the evaluation relationship with the algorithm tracing relationship, and use consistency between the evaluation relationship and the algorithm tracing relationship as an operating state evaluation indicator.

In a specific implementation process of this embodiment, the evaluation module includes: a first calculation unit, where the first calculation unit is configured to: obtain a fault factor that affects the weight of the operating state evaluation indicator, and calculate a fault factor information entropy of the operating state evaluation indicator; and
a second calculation unit, where the second calculation unit is configured to combine fault factor information entropies of a plurality of operating state evaluation indicators to obtain an operating state evaluation joint entropy; an adjustment unit, where the adjustment unit is configured to adjust the weight of the operating state evaluation indicator based on the operating state evaluation joint entropy; and an evaluation unit, where the evaluation unit performs operating state evaluation on the electric energy data acquisition equipment based on an adjustment result of the weight of the operating state evaluation indicator.

The system for evaluating an operating state of electric energy data acquisition equipment further includes an alarm module, configured to raise an exception operating state alarm on electric energy data acquisition equipment whose operating state evaluation joint entropy is less than a first exception threshold.

Embodiment 3: This embodiment provides a computer readable medium storing a computer program thereon. The computer program is executed by a processor to implement the method for evaluating an operating state of electric energy data acquisition equipment in Embodiment 1. The method specifically includes the following steps:

Step 1. Analyze regulation information of the electric energy data acquisition equipment, and obtain an operating state evaluation baseline of the electric energy data acquisition equipment.

Step 2. Acquire operating profile data of the electric energy data acquisition equipment, and establish an operating state evaluation rule based on the operating profile data and the operating state evaluation baseline.

Step 3. Perform operating state evaluation on the electric energy data acquisition equipment based on the operating state evaluation rule, to obtain an operating state evaluation result, and in an operating state evaluation process of the electric energy data acquisition equipment, adjust a weight of the operating state evaluation indicator based on a fault factor of the operating state evaluation rule.

The objectives, technical solutions, and beneficial effects of the present disclosure are further described in detail in the above specific implementations. It should be understood that the above described are only specific implementations of the present disclosure and are not intended to limit the protection scope of the present disclosure. Any modification, equivalent replacement, improvement, and the like made within the spirit and principle of the present disclosure should fall within the protection scope of the present disclosure.

What is claimed is:

1. A method for evaluating an operating state of electric energy data acquisition equipment, comprising:
analyzing regulation information of the electric energy data acquisition equipment, and obtaining an operating state evaluation baseline of the electric energy data acquisition equipment, specifically comprising:
obtaining the regulation information of the electric energy data acquisition equipment;
recognizing operating state red line information from the regulation information, wherein the operating state red line information comprises text recognition information and content recognition information; and
using the operating state red line information as the operating state evaluation baseline of the electric energy data acquisition equipment;
acquiring operating profile data of the electric energy data acquisition equipment, and establishing an operating state evaluation rule based on the operating profile data and the operating state evaluation baseline, specifically comprising:
clustering the operating profile data to distinguish between invalid exception data and equipment fault data, wherein the equipment fault data comprises an equipment fault type, a fault cause, and a feature data item that correspond to each other;
forming an evaluation relationship between the equipment fault data and the fault cause based on the operating state evaluation baseline and exception detection in an equipment fault handling process, specifically comprising:
obtaining a current feature data item of the electric energy data acquisition equipment, comparing the current feature data item with a corresponding operating state evaluation baseline, and if the current feature data item exceeds the corresponding operating state evaluation baseline, obtaining a corresponding fault cause through matching;
tracing an equipment fault cause based on a tracing algorithm, and forming an algorithm tracing relationship between the equipment fault data and the fault cause; and
associating the evaluation relationship with the algorithm tracing relationship, and using consistency between the evaluation relationship and the algorithm tracing relationship as an operating state evaluation indicator; and
performing operating state evaluation on the electric energy data acquisition equipment based on the operating state evaluation rule, to obtain an operating state evaluation result, and in an operating state evaluation process of the electric energy data acquisition equipment, adjusting a weight of the operating state evaluation indicator based on a fault factor of the operating state evaluation rule, specifically comprising:
obtaining a fault factor that affects the weight of the operating state evaluation indicator, and calculating a fault factor information entropy of the operating state evaluation indicator;
combining fault factor information entropies of a plurality of operating state evaluation indicators to obtain an operating state evaluation joint entropy;
adjusting the weight of the operating state evaluation indicator based on the operating state evaluation joint entropy; and
performing operating state evaluation on the electric energy data acquisition equipment based on an adjustment result of the weight of the operating state evaluation indicator.

2. The method for evaluating an operating state of electric energy data acquisition equipment according to claim 1, before the establishing an operating state evaluation rule based on the operating profile data and the operating state evaluation baseline, further comprising:
cleaning exception data of the operating profile data, and fitting data points in an exception data range to eliminate the exception data.

3. The method for evaluating an operating state of electric energy data acquisition equipment according to claim 1, wherein the combining fault factor information entropies of a plurality of operating state evaluation indicators to obtain an operating state evaluation joint entropy specifically comprises:
obtaining fault factor information entropies of a plurality of operating state evaluation indicators, and using an intersection set of the fault factor information entropies of the plurality of operating state evaluation indicators as a conditional entropy of the operating state evaluation indicator; and
adding the fault factor information entropies of the operating state evaluation indicators, and performing summation on the fault factor information entropies and the conditional entropy of the operating state evaluation indicator to obtain the operating state evaluation joint entropy.

4. The method for evaluating an operating state of electric energy data acquisition equipment according to claim 1, wherein the performing operating state evaluation on the electric energy data acquisition equipment based on the operating state evaluation rule, to obtain an operating state evaluation result further comprises the method: raising an exception operating state alarm on electric energy data acquisition equipment whose operating state evaluation joint entropy is less than a first exception threshold.

5. A system for evaluating an operating state of electric energy data acquisition equipment, wherein the system is configured to implement the method for evaluating an operating state of electric energy data acquisition equipment according to claim 1, and the system comprises:
an analysis module, configured to: analyze regulation information of the electric energy data acquisition equipment, and obtain an operating state evaluation baseline of the electric energy data acquisition equipment;
an establishment module, configured to: acquire operating profile data of the electric energy data acquisition equipment, and establish an operating state evaluation rule based on the operating profile data and the operating state evaluation baseline; and
an evaluation module, configured to: perform operating state evaluation on the electric energy data acquisition equipment based on the operating state evaluation rule, to obtain an operating state evaluation result, and in an operating state evaluation process of the electric energy data acquisition equipment, adjust a weight of the operating state evaluation indicator based on a fault factor of the operating state evaluation rule.

6. The system for evaluating an operating state of electric energy data acquisition equipment according to claim 5, wherein the analysis module specifically comprises:
a first acquisition unit, configured to: obtain the regulation information of the electric energy data acquisition equipment;
a recognition unit, configured to: recognize operating state red line information from the regulation information, wherein the operating state red line information comprises text recognition information and content recognition information; and
an output unit, configured to: use the operating state red line information as the operating state evaluation baseline of the electric energy data acquisition equipment for output.

7. The system for evaluating an operating state of electric energy data acquisition equipment according to claim 5, wherein the establishment module specifically comprises:
a second acquisition unit, configured to: acquire operating profile data of the electric energy data acquisition equipment;
a preprocessing unit, configured to: clean exception data of the operating profile data, and fit data points in an exception data range to eliminate the exception data;
a clustering unit, configured to: cluster the operating profile data to distinguish between invalid exception data and equipment fault data, wherein the equipment fault data comprises an equipment fault type, a fault cause, and a feature data item that correspond to each other;
a first construction unit, configured to: form an evaluation relationship between the equipment fault data and the fault cause based on the operating state evaluation baseline and exception detection in an equipment fault handling process;
a second construction unit, configured to: trace an equipment fault cause based on a tracing algorithm, and form an algorithm tracing relationship between the equipment fault data and the fault cause; and
a second output unit, configured to: associate the evaluation relationship with the algorithm tracing relationship, and use consistency between the evaluation relationship and the algorithm tracing relationship as an operating state evaluation indicator.

8. The system for evaluating an operating state of electric energy data acquisition equipment according to claim 5, wherein the evaluation module comprises:
a first calculation unit, configured to: obtain a fault factor that affects the weight of the operating state evaluation indicator, and calculate a fault factor information entropy of the operating state evaluation indicator; and
a second calculation unit, configured to: combine fault factor information entropies of a plurality of operating state evaluation indicators to obtain an operating state evaluation joint entropy; an adjustment unit, wherein the adjustment unit is configured to adjust the weight of the operating state evaluation indicator based on the operating state evaluation joint entropy; and an evaluation unit, wherein the evaluation unit performs operating state evaluation on the electric energy data acquisition equipment based on an adjustment result of the weight of the operating state evaluation indicator.

9. The system for evaluating an operating state of electric energy data acquisition equipment according to claim 5, wherein the system further comprises an alarm module, configured to: raise an exception operating state alarm on electric energy data acquisition equipment whose operating state evaluation joint entropy is less than a first exception threshold.

10. A computer readable medium storing a computer program thereon, wherein the computer program is executed by a processor to implement the method for evaluating an operating state of electric energy data acquisition equipment according to claim 1.
